(19) United States
(12) Patent Application Publication
(10) Pub. No.: US 2022/0406901 A1
(43) Pub. Date: Dec. 22, 2022

(54) METHOD FOR MANUFACTURING METAL GATE MOS TRANSISTOR

(71) Applicant: Shanghai Huali Integrated Circuit Corporation, Shanghai (CN)

(72) Inventor: Wenyin Weng, Shanghai (CN)

(21) Appl. No.: 17/839,313

(22) Filed: Jun. 13, 2022

(30) Foreign Application Priority Data
Jun. 21, 2021 (CN) 202110685045.7

(51) Int. Cl. H01L 29/40; H01L 29/66

(52) U.S. Cl. CPC H01L 29/401; H01L 29/66795; H01L 29/66545; H01L 29/45

(57) ABSTRACT

The present application discloses a method for manufacturing a metal gate MOS transistor, comprising: step 1, forming metal gates; step 2, forming a first dielectric layer disposed on the metal gates and the zeroth interlayer film; step 3, forming an opening for the zeroth metal layer; step 4, forming a first Ti layer and a second TiN layer; and step 5, filling the opening of the zeroth metal layer with a metal material. After step 1 and before step 4, performing the first annealing at a first temperature to adjust a threshold voltage of the metal gate MOS transistor to a target value. After step 4 and before step 5, performing the second annealing at a second temperature lower than the first temperature to adjust on-resistance of the metal gate MOS transistor.

### CROSS-REFERENCES TO RELATED APPLICATIONS

This application claims the priority to Chinese patent application No. CN 202110685045.7, filed on Jun. 21, 2021, and entitled “METHOD FOR MANUFACTURING METAL GATE MOS TRANSISTOR”, the disclosure of which is incorporated herein by reference in entirety.

### TECHNICAL FIELD

The present application relates to a method for manufacturing semiconductor integrated circuits, in particular, to a method for manufacturing a metal gate (MG) MOS transistor.

### BACKGROUND

With development of the CMOS technologies, the conventional silicon dioxide gate dielectric and polysilicon gate (Poly SiON) transistors have reached their physical limits. For example, the problems such as an excessive leakage current caused by the quantum tunneling effect and the depletion of a polysilicon gate seriously have affected the performance of semiconductor devices. Starting from the 45 nm technology node, the high dielectric constant layer (HK) and a metal gate (MG) (HKMG) stacked transistors developed on the basis of the HKMG process effectively have solved the above technical problems.

The gate structure of a high dielectric constant metal gate MOS transistor adopts an HKMG. The metal gate includes a metal work function layer and a metal conductive material layer, and the metal work function layer is used to adjust the threshold voltage of the device. Different work functions of the metal work function layer correspond to different flat band voltages of the device, resulting in different threshold voltages of the device. The metal work function layer of NMOS is an N-type metal work function layer. The work function of the N-type metal work function layer is usually close to the bottom of the conduction band of a semiconductor substrate such as a silicon substrate, so that the threshold voltage of NMOS can be reduced, thereby increasing the device speed and reducing the power consumption. The metal work function layer of PMOS is a P-type metal work function layer. The work function of the P-type metal work function layer is usually close to the top of the valence band of a semiconductor substrate such as a silicon substrate, so that the threshold voltage of PMOS, i.e., the absolute value of the threshold voltage of PMOS can be reduced, thereby increasing the device speed and reducing the power consumption.

The process of forming the metal gate usually adopts a gate-last process, and a gate dielectric layer including a high dielectric constant layer adopts an HK-first process or an HK-last process.

In the gate-last process, a dummy polysilicon gate (Dummy Poly Silicon) is required and used to define a region for forming a gate structure, and then sidewall and source and drain regions are formed in a self-aligned manner. After an interlayer film which fills a spacing region between the dummy polysilicon gates is formed, the interlayer film is usually planarized to expose the surface of the dummy polysilicon gate, then the dummy polysilicon gate is removed and a gate trench is formed in a region where the dummy polysilicon gate is removed, and then an HKMG is formed in the gate trench.

An HKMG is provided in an existing MOS transistor.

The material of the high dielectric constant layer may include one of silicon dioxide (SiO2), silicon nitride (Si3N4), aluminum oxide (Al2O3), tantalum pentoxide (Ta2O5), yttrium oxide (Y2O3), and hafnium silicate oxide (HfSiO4), hafnium dioxide (HfO2), lanthanum oxide (La2O3), zirconium dioxide (ZrO2), strontium titanate (SrTiO3), and zirconium silicate oxide (ZrSiO4), etc.

An interface layer (IL) is usually provided between the high dielectric constant layer and the semiconductor substrate. Among the existing techniques, the material of the high dielectric constant layer usually adopts HfO2, and the interface layer usually adopts SiO2.

The gate dielectric layer further includes a barrier layer composed of a titanium nitride (TiN) layer and a tantalum nitride (TaN) layer. The barrier layer is located on the top of the high dielectric constant layer, and usually the barrier layer is also located at the bottom of the work function layer, so the barrier layer between the gate dielectric layer and the work function layer is also referred to as a bottom barrier layer (BBM).

The metal work function layer is formed between the bottom barrier layer and the metal conductive material layer, and a capping layer is usually formed between the metal work function layer and the metal conductive material layer. The capping layer is located on the top of the work function layer, and usually is also referred to as a top barrier layer (TBM).

The metal work function layer varies according to the type of the MOS transistor:

For a P-type MOS transistor, i.e., a PMOS transistor, the metal work function layer thereof is a P-type work function layer. The work function of the P-type work function layer is near the valence band of a semiconductor substrate such as a silicon substrate. In the prior art, the P-type work function layer usually adopts TiN.

Similarly, for an N-type MOS transistor, i.e., an NMOS transistor, the metal work function layer thereof is an N-type work function layer. The work function of the N-type work function layer is near the conduction band of a semiconductor substrate such as a silicon substrate. In the prior art, the N-type work function layer usually adopts TiAl.

For the gate structure of the existing planar MOS transistor, the channel region is controlled only from one side. With continuous development of the semiconductor technology, for example, when the process node is reduced to below 25 nm, the existing planar MOS transistor may have a problem of a large electric leakage, and thus a fin transistor (FinFET) is usually adopted. In the FinFET, a fin is formed on a semiconductor substrate by patterning the semiconductor substrate, and a gate structure covers the top surface and the side surface of the fin, increasing the width of the channel region, thereby improving the conductivity of the device and achieving better electrical performance.

In a FinFET of the process node below 14 nm, a zeroth metal layer (M0) is usually adopted to achieve the contact with a source region, a drain region, and a metal gate of the FinFET. FIG. 1 is a flowchart of an existing method for manufacturing a metal gate MOS transistor. In FIG. 1, each step is represented by a simple abbreviation, and only the steps related to the technical problem of the present application are illustrated, including the following steps:

Step S101. An RMG process is performed, RMG being a replacement of metal gate process, that is, a dummy polysilicon gate is removed, and then a metal gate is formed in a region where the dummy polysilicon gate is removed.

Step S102. A tungsten etching-back (WEB) process is performed. A metal conductive material layer of the metal gate usually adopts tungsten, and the WEB is one kind of metal conductive material layer etching-back.

Step S103. A self-aligned contact (SAC) silicon nitride (SiN) deposition (Dep.)/chemical mechanical polishing (CMP) process, i.e., SAC SiN Dep./CMP, is performed, including two sub-steps: first depositing SiN to define a self-aligned contact and then performing CMP.

Step S104. An M0 Etch process is performed, wherein M0 represents a zeroth metal layer, Etch represents etching, and M0 Etch represents etching a region for forming the zeroth metal layer to form an opening for filling the zeroth metal layer.

Step S105. Ti/TiN & annealing processes are performed, wherein annealing represents an annealing process, that is, a Ti layer and a TiN layer are formed in the opening of the zeroth metal layer and then annealing is performed. The annealing process alloys the Ti layer with a bottom contact region such as the semiconductor material, thereby reducing contact resistance and thereby reducing on-resistance.

Step S106. A tungsten (W) fill process is performed, that is, the opening of the zeroth metal layer is filled with tungsten.

Step S107. A BEoL process is performed, wherein BEoL represents the back end of line, that is, a subsequent back end of line process is performed.

In the existing method, the annealing in step S105 is not only used to reduce the contact resistance, but also to adjust the threshold voltage (Vt). However, reducing the contact resistance and adjusting the threshold voltage have opposite requirements to the annealing process. Appropriate threshold voltage and on-resistance cannot be achieved at the same time by adjusting the temperature of the annealing process.

It can be seen from the above that the annealing process of the zeroth metal layer not only affects the on-resistance, but also affects the threshold voltage of the device. In order to reduce the on-resistance of the device, it is necessary to reduce the annealing temperature, but the reduction of the annealing temperature may cause the threshold voltage of the device to deviate from a target value. Therefore, the adjustments to the on-resistance and the threshold voltage achieved by the annealing process of the zeroth metal layer are contradictory, that is, it is impossible to obtain appropriate on-resistance and threshold voltage at the same time. Details are described in the following.

FIG. 2A is a chart of on-resistance (Ron) versus the inverse of gate voltage minus threshold gate voltage (Vg−Vtgm)⁻¹ at two different annealing temperatures of an NMOS device, the NMOS device is a zeroth-metal-layer formed by an existing technique. Curve 101 represents the on-resistance when the annealing temperature is 600° C., and curve 102 represents the on-resistance when the annealing temperature is 650° C. The Ron values in the curve 101 are relatively lower than those in the curve 102 for the save (Vg−Vtgm)⁻¹ on the X-axis, that is, the on-resistance Ron of the NMOS device is reduced by about 7% by reducing the annealing temperature of the annealing process of the zeroth metal layer.

FIG. 2B is a chart comparing the threshold voltages on two wafers containing metal gate MOS transistors which are annealed at different temperatures for the zeroth metal layer, applying an existing process. In FIG. 2B, the devices on two wafers annealed at two temperatures show their resultant threshold voltages on the Y-axis as data group 103 at 600° C. and data group 104 at 650° C. The mean of threshold voltages of data group 103 deviates from the mean of threshold voltage of data group 104 by +100 mV.

FIG. 3A is a chart of on-resistance (Ron) versus the inverse of gate voltage minus threshold gate voltage (Vg−Vtgm) at two different annealing temperatures for the zeroth-metal-layer of a PMOS device, formed by an existing technique. The curve 201 represents the on-resistance when the annealing temperature is 600° C., and the curve 202 represents the on-resistance when the annealing temperature is 650° C. The Ron values in the curve 201 are relatively lower than those in the curve 202 for the save (Vg−Vtgm)⁻¹ on the X-axis, that is, the on-resistance Ron of the NMOS device is reduced by about 7% by reducing the annealing temperature of the annealing process of the zeroth metal layer.

FIG. 3B is a chart comparing the threshold voltages on two wafers containing metal gate MOS transistors which are annealed at different temperatures for the zeroth metal layer, applying an existing process. In FIG. 3B, the devices on two wafers annealed at two temperatures show their resultant threshold voltages on the Y-axis as data group 203 at 600° C. and data group 204 at 650° C. The mean of threshold voltages of data group 203 deviates from the mean of threshold voltage of data group 204 by −50 mV.

### BRIEF SUMMARY

According to some embodiments in this application, the method for manufacturing a metal gate MOS transistor provided by the present application includes the following steps:

step 1, completing a process of forming a metal gate on a semiconductor substrate, wherein a zeroth interlayer film is formed in a space region between the metal gates;

step 2, forming a first dielectric layer covering the metal gate and the zeroth interlayer film;

step 3, selecting a region for forming a zeroth metal layer, and etching the first dielectric layer and the zeroth interlayer film in the region for forming the zeroth metal layer to form an opening of the zeroth metal layer;

step 4, forming a first Ti layer and a second TiN layer on the inner side surface of the opening of the zeroth metal layer; and

step 5, filling the opening of the zeroth metal layer with a metal material to form the zeroth metal layer.

After step 1 and before step 4, the method further includes:

performing the first annealing at a first temperature, the first annealing being used for adjusting a threshold voltage of the metal gate MOS transistor, i.e., adjusting the threshold voltage of the metal gate MOS transistor to a target value by configuring the first temperature.

After step 4 and before step 5, the method further includes:

performing second annealing at a second temperature, the second annealing being used for adjusting on-resistance of the metal gate MOS transistor, i.e., reducing the on-resistance of the metal gate MOS transistor by lowering the second temperature, and the second temperature being lower than the first temperature to ensure that the threshold voltage of the metal gate MOS transistor is determined by the first annealing.

In some cases, in step 1, the metal gate is formed by means of a gate-last process.

In some cases, the gate-last process includes:

removing a dummy polysilicon gate; and

forming the metal gate in a region where the dummy polysilicon gate is removed.

In some cases, the metal gate includes a metal work function layer and a metal conductive material layer stacked in sequence.

In some cases, the material of the metal conductive material layer includes tungsten.

In some cases, the material of the zeroth metal layer includes tungsten.

In some cases, the first temperature is in the range of 650° C.-700° C.

In some cases, the second temperature is in the range of 550° C.-600° C.

In some cases, after forming the metal gate in step 1, the method further includes a step of etching back the metal conductive material layer.

In some cases, before forming the first dielectric layer in step 2, the method further includes a step of forming a second dielectric layer to fill an etching-back region of the metal conductive material layer.

The material of the first dielectric layer is the same as the material of the zeroth interlayer film, and the material of the second dielectric layer includes silicon nitride.

The second dielectric layer is formed by means of a deposition process, and after the deposition process, the method further includes performing planarization by means of a chemical mechanical polishing process.

In some cases, in step 1, a gate dielectric layer is isolated between the metal gate and the semiconductor substrate.

In some cases, the gate dielectric layer includes a high dielectric constant layer.

In some cases, the metal gate MOS transistor is a fin transistor, a fin is formed on the semiconductor substrate, and the fin is formed by patterning the semiconductor substrate.

In a region for forming the metal gate, the metal gate covers the top surface and the side surface of the fin.

In some cases, in step 1, a source region and a drain region are formed in the fins on two sides of the metal gate.

In some cases, the metal gate MOS transistor includes an NMOS and a PMOS.

In the present application, during the process of forming the zeroth metal layer after the metal gate is formed, the annealing process of the zeroth metal layer is divided into the first annealing process performed before the formation of the first TiN layer and the second TiN layer, and the second annealing process performed after the formation of the first Ti layer and the second TiN layer. An annealing temperature of the first annealing, i.e., the first temperature, is configured to be greater than an annealing temperature of the second annealing, i.e., the second temperature, so as to ensure that the threshold voltage of the device is determined by the first annealing, such that the configuration of the second temperature is not limited by the requirement of satisfying the threshold voltage and the second temperature can be lowered to satisfy the requirement of reducing the on-resistance of the device. Therefore, the present application can eliminate contradictory impacts of the annealing process of the zeroth metal layer on the on-resistance and the threshold voltage and achieve appropriate on-resistance and threshold voltage at the same time.

### BRIEF DESCRIPTION OF THE DRAWINGS

The present application is described in detail below with reference to the drawings and specific implementations.

FIG. 1 is a process flow chart of an existing method for manufacturing a metal gate MOS transistor.

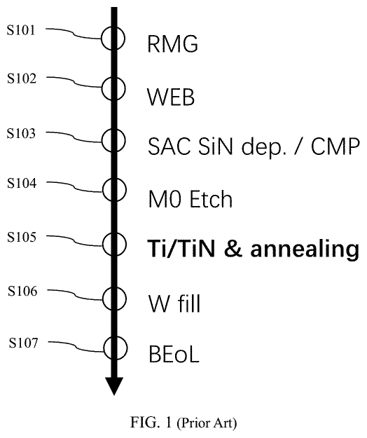

FIG. 2A is a chart of on-resistance (Ron) versus the inverse of gate voltage minus threshold gate voltage (Vg−Vtgm)⁻¹ at two different annealing temperatures at zeroth-metal-layer of an NMOS device.

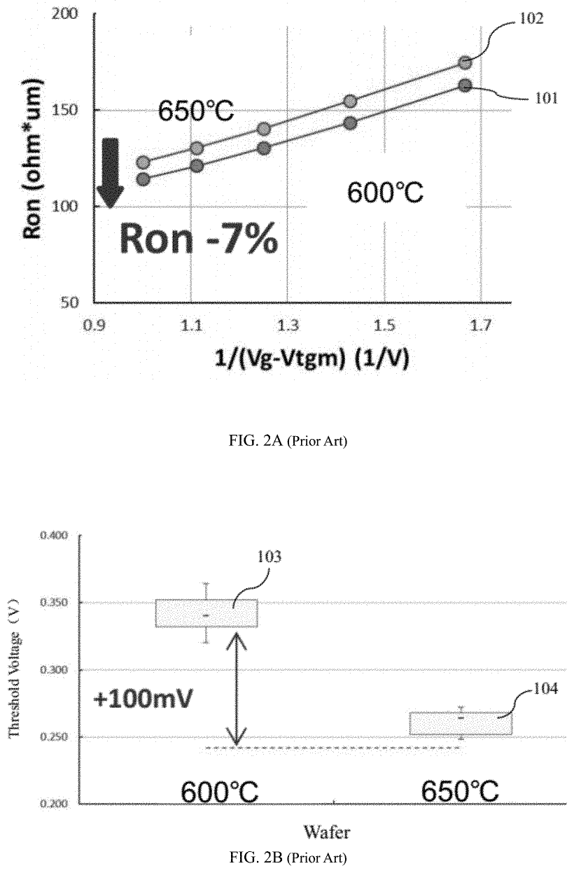

FIG. 2B is a chart comparing the threshold voltages on two wafers containing metal gate MOS transistors which are annealed at different temperatures for the zeroth metal layer, applying an existing process.

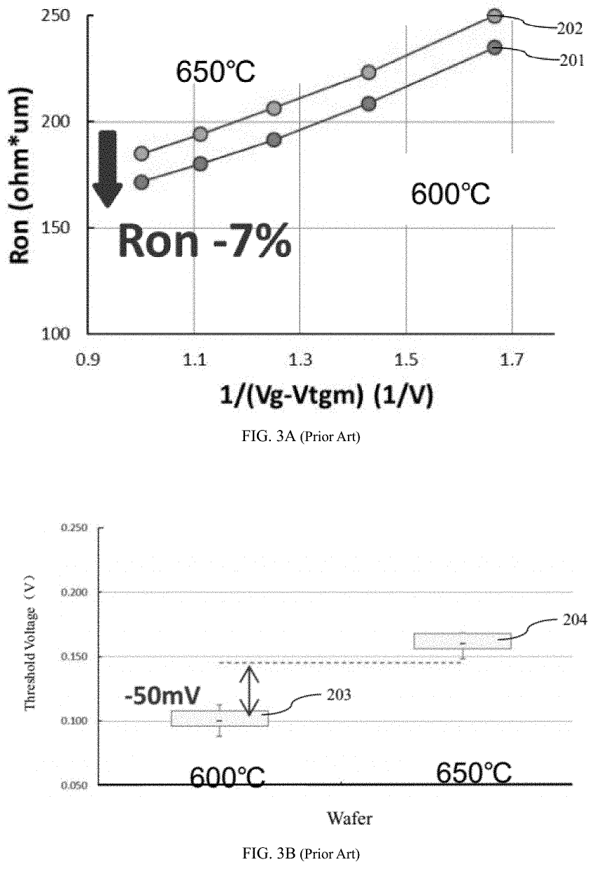

FIG. 3A is a chart of on-resistance (Ron) versus the inverse of gate voltage minus threshold gate voltage (Vg−Vtgm)⁻¹ at two different annealing temperatures at zeroth-metal-layer of an PMOS device by the existing method.

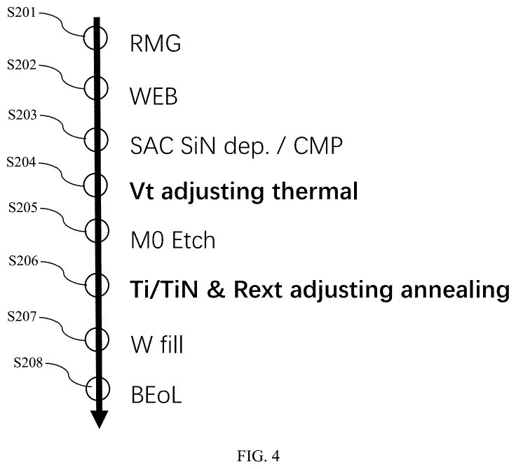

FIG. 3B is a chart comparing the threshold voltages on two wafers containing metal gate MOS transistors which are annealed at different temperatures for the zeroth metal layer, applying an existing process.

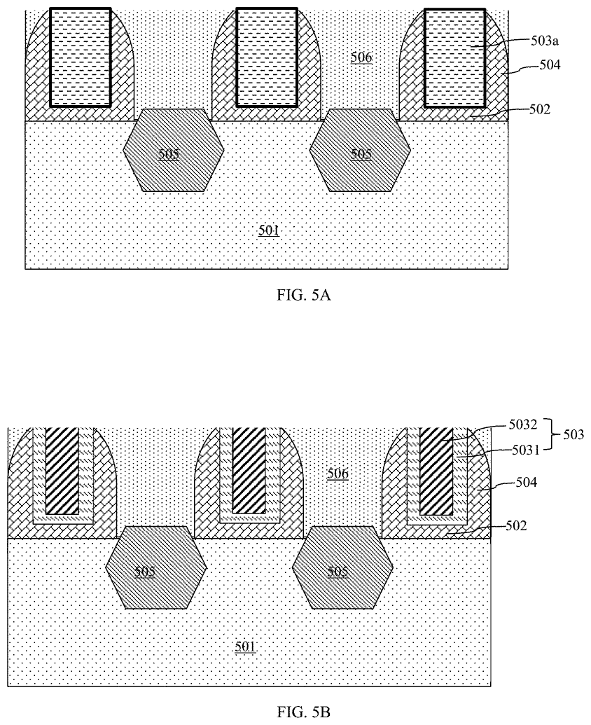

FIG. 4 is a process flow chart of the method for manufacturing a metal gate MOS transistor, according to an embodiment of the present application.

FIGS. 5A-5I illustrate cross sections of the device structures in steps of the method for manufacturing a metal gate MOS transistor according to the embodiment of the present application.

FIG. 6A is a chart of on-resistance (Ron) versus the inverse of gate voltage minus threshold gate voltage (Vg−Vtgm)⁻¹ at two different annealing temperatures at zeroth-metal-layer of an NMOS device, by the method for manufacturing the metal gate MOS transistor according to the embodiment of the present application.

FIG. 6B is a chart comparing the threshold voltages containing metal gate NMOS transistors on two wafers which are annealed at different temperatures for the zeroth metal layer, according to the embodiment of the present application.

FIG. 7A is a chart of on-resistance (Ron) versus the inverse of gate voltage minus threshold gate voltage (Vg−Vtgm)⁻¹ at two different annealing temperatures at zeroth-metal-layer of an PMOS device, by the method for manufacturing the metal gate MOS transistor according to the embodiment of the present application.

FIG. 7B is a chart comparing the threshold voltages containing metal gate PMOS transistors on two wafers which are annealed at different temperatures for the zeroth metal layer, according to the embodiment of the present application.

### DETAILED DESCRIPTION

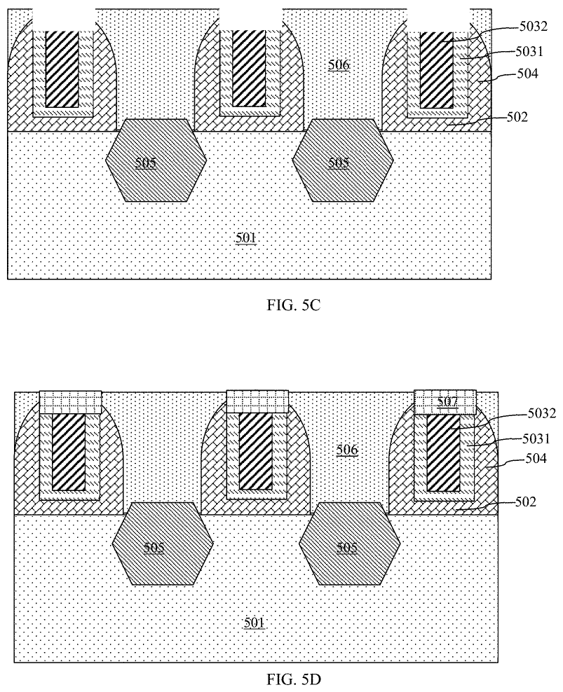

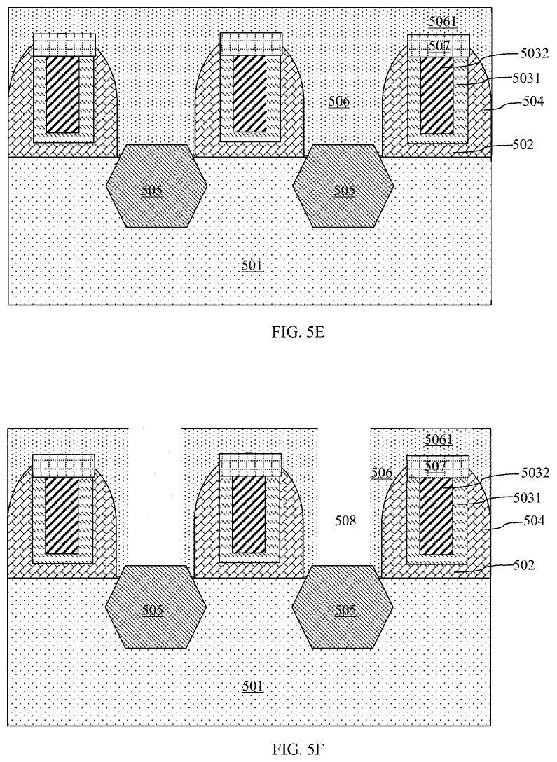

FIG. 4 is a process flow chart of a method for manufacturing a metal gate MOS transistor according to an embodiment of the present application. FIGS. 5A-5I illustrate cross sections of the device structures in steps of the method for manufacturing a metal gate MOS transistor according to the embodiment of the present application. The method for manufacturing a metal gate MOS transistor according to this embodiment of the present application includes the following steps:

Step 1: forming a zeroth interlayer film 506 on a semiconductor substrate 501, patterning metal gates 503 in the zeroth interlayer film 506, wherein the zeroth interlayer film 506 is configured to be in a spacing region between adjacent two of the metal gates 503.

In this embodiment of the present application, the metal gates 503 are patterned by means of a gate-last process.

Referring to FIG. 5A, dummy polysilicon gates 503a are first formed in the forming regions of the metal gates 503 before the metal gates 503. A gate dielectric layer 502 is formed at the bottom of the dummy polysilicon gates 503a, and sidewalls 504 are formed on the side surfaces of the dummy polysilicon gates 503a. A source region and a drain region are formed in the semiconductor substrate 501 on two sides of each of the dummy polysilicon gates 503a. With shrinking of the critical dimension in the continuing process nodes, it is necessary to introduce a strain structure to the source region and the drain region, so as to improve the mobility of channel carriers. In FIG. 5A, an embedded epitaxial layer 505 is formed in regions for forming the source region and the drain region, so as to improve the mobility of channel carriers by means of the stress of the embedded epitaxial layer 505.

The metal gate MOS transistor includes an NMOS and a PMOS.

The material of the embedded epitaxial layer 505 of the NMOS includes SiP, and the material of the embedded epitaxial layer 505 of the PMOS includes SiGe.

The source region and the drain region are formed in the embedded epitaxial layer 505 on two sides of each of the dummy polysilicon gates 503a in a self-aligned manner by means of source-drain implantation. After the implantation of the source region and the drain region is completed and annealing is performed, the method further includes a step of forming the zeroth interlayer film 506 in the spacing region between the dummy polysilicon gates 503a.

The semiconductor substrate 501 includes a silicon substrate. The metal gate MOS transistor is a fin transistor (FinFET), and a fin is formed on the semiconductor substrate 501 by patterning the semiconductor substrate 501. Each of the dummy polysilicon gates 503a covers the side surfaces and the top surface of the fin, and the source region and the drain region are formed in the fins on two sides of each of the dummy polysilicon gates 503a.

The gate-last process includes the following:

Referring FIG. 5B, the dummy polysilicon gates 503a are removed.

The metal gates 503 are formed in a regions where the dummy polysilicon gates 503a are removed.

Each of the metal gate 503 includes a metal work function layer 5031 and a metal conductive material layer 5032 stacked in sequence. The material of the metal conductive material layer 5032 includes tungsten.

In this embodiment of the present application, a gate dielectric layer 502 is isolated between each one of the metal gates 503 and the semiconductor substrate 501. In this embodiment of the present application, the gate dielectric layer 502 adopts a HK-first process, that is, the gate dielectric layer 502 is formed before the dummy polysilicon gates 503a are formed and is remains after the dummy polysilicon gates 503a are removed. In other embodiments, the gate dielectric layer 502 can also be formed by means of a HK-last process, in which case a dummy gate dielectric layer is required to replace the gate dielectric layer 502 before the dummy polysilicon gates 503a are formed, the dummy gate dielectric layer needs to be removed after the dummy polysilicon gates 503a are removed, and then the gate dielectric layer 502 is formed.

The gate dielectric layer 502 includes a high dielectric constant layer.

The step of forming the metal gates 503 in step 1 corresponds to the replacement of metal gate (RMG) step S201 in FIG. 4, that is, the metal gates 503 are formed by means of a gate replacement process.

Referring to FIG. 5C, after forming the metal gate 503, the method further includes performing an etching-back process of the metal conductive material layer 5032, i.e., WEB in step S202, wherein WEB is the tungsten etching-back process. The etching-back process of the metal conductive material layer 5032 also removes the metal work function layer 5031 on two sides of the metal conductive material layer 5032.

Step 2. Referring to FIG. 5E, a first dielectric layer 5061 is disposed on the metal gates 503 and the zeroth interlayer film 506.

In this embodiment of the present application, referring to FIG. 5D, before forming the first dielectric layer 5061, the method further includes a step of forming a second dielectric layer 507 to fill the void region left by the etching-back process on the metal conductive material layer 5032 and the metal work function layer 5031.

The material of the first dielectric layer 5061 is the same as the material of the zeroth interlayer film 506, and the material of the zeroth interlayer film 506 includes an oxide layer or a low dielectric constant layer.

The material of the second dielectric layer 507 includes silicon nitride. The second dielectric layer 507 is formed by means of a deposition process, and after the deposition process, the method further includes performing planarization by means of a chemical mechanical polishing process, i.e., SAC SiN (a self-aligned contact and silicon nitride) Dep./CMP corresponding to step S203 in FIG. 4.

Step 3. Referring to FIG. 5F, regions for forming the zeroth metal layer is selected, and the first dielectric layer 5061 and the zeroth interlayer film 506 in the selected regions for are patterned to form openings 508 in the zeroth metal layer. FIG. 5F shows the openings 508 aligned to the top surface of the embedded epitaxial layers 505 for the source region and the drain region.

In this embodiment of the present application, step 3 is to prepare for the M0 Etch of step S205 in FIG. 4.

Referring to FIG. 5G, subsequently, first annealing process 601 is performed at a first temperature. The first annealing process 601 is applied for adjusting the threshold voltage of the metal gate MOS transistors, i.e., adjusting the threshold voltage of the metal gate MOS transistors to a target value by applying the first annealing temperature. The first annealing process 601 has the process term of Vt adjusting thermal as in the step S204 in FIG. 4, wherein Vt is the threshold voltage, and Vt adjusting thermal is the brief term of the adjustment of Vt by a thermal process.

In an example, the first annealing temperature is in the range of 650° C.-700° C.

In this embodiment of the present application, the first annealing process 601 is performed after the formation of the opening 508. In other embodiments, the first annealing process 601 first annealing process 601 can be performed after step 1 and before the formation of the opening 508, as long as the threshold voltage of the metal gate MOS transistor can be adjusted to the target value.

Step 4. Referring to FIG. 5H, a first Ti layer 509 and a second TiN layer 510 are formed on the inner side surface of the opening 508 of the zeroth metal layer.

In this embodiment of the present application, step 4 corresponds to Ti/TiN of step S206 in FIG. 4.

Referring to FIG. 5I, subsequently, second annealing process 602 is performed at a second temperature. The second annealing process 602 is used for adjusting on-resistance of the metal gate MOS transistor, i.e., reducing the on-resistance of the metal gate MOS transistor by lowering the second temperature. The second temperature is lower than the first temperature to ensure that the threshold voltage of the metal gate MOS transistor is determined by the first annealing process 601. The second annealing process 602 is represented by Rext adjusting annealing of the step S206 in FIG. 4, here Rext is the external resistance, which is usually determined by the contact resistance formed by the zeroth metal layer and the bottom doped region, and Rext adjusting annealing is the process term for reducing the on-resistance of the device by lowering the annealing process temperature.

Usually, the second annealing process 602 also affects the threshold voltage of the metal gate MOS transistor. However, in this embodiment of the present application, the first annealing process 601 at a higher temperature is performed before the second annealing process 602, so that the threshold voltage of the metal gate MOS transistor is completely determined by the first annealing process 601, thereby eliminating the adverse effect of the second annealing process 602 on the threshold voltage of the metal gate MOS transistors.

In an example, the second annealing temperature is in the range of 550° C.-600° C.

Step 5. The opening 508 into the zeroth metal layer is filled with a metal material to form the zeroth metal layer.

In this embodiment of the present application, the material of the zeroth metal layer includes tungsten (W). Step 5 is the step S207 of W fill in FIG. 4.

Then BEoL step S208, i.e., a back end of line process, is performed.

In this embodiment of the present application, during the process of forming the zeroth metal layer after the metal gates 503 are formed, the annealing process of the zeroth metal layer is divided into the first annealing process 601 performed before the formation of the first TiN layer and the second TiN layer 510 and the second annealing process 602 performed after the formation of the first Ti layer 509 and the second TiN layer 510. An annealing temperature of the first annealing process 601, i.e., the first annealing temperature, is configured to be greater than an annealing temperature of the second annealing process 602, i.e., the second annealing temperature, so as to ensure that the threshold voltage of the device is determined by the first annealing process 601, such that the configuration of the second annealing temperature is not limited by the requirement of satisfying the threshold voltage and the second annealing temperature can actually be lowered to satisfy the requirement of reducing the on-resistance of the device. Therefore, this embodiment of the present application can eliminate contradictory impacts of the annealing process for the zeroth metal layer on the on-resistance and the threshold voltage, and achieve appropriate on-resistance and threshold voltage at the same time.

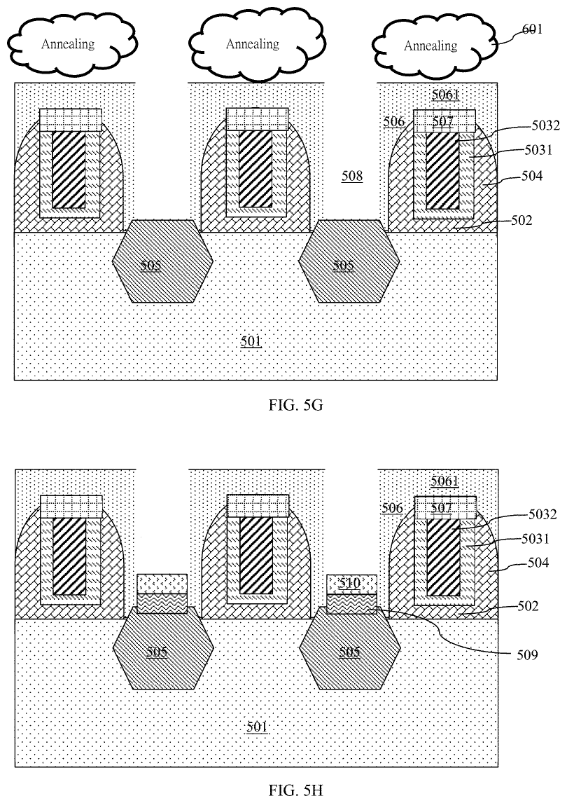

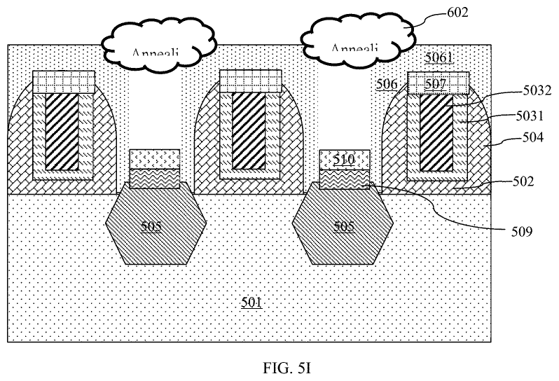

FIG. 6A is a chart of on-resistance (Ron) versus the inverse of gate voltage minus threshold gate voltage (Vg−Vtgm)⁻¹ at two different annealing temperatures at zeroth-metal-layer of an NMOS device, by the method for manufacturing the metal gate MOS transistor according to the embodiment of the present application. Curve 301 represents the on-resistance when the first annealing process 601 and the second annealing process 602 according to this embodiment of the present application are performed. The first annealing temperature and the second annealing temperature in FIG. 6A are 650° C. and 600° C., respectively. In FIG. 6A, 650° C.+600° C. applied to indicate that the first annealing process 601 and the second annealing process 602 of this embodiment of the present application are performed. Curve 302 represents an on-resistance obtained after the annealing process of the zeroth metal layer at 650° C. is performed. It can be seen that the value of the curve 301 is lower by about 5%. Therefore, in this embodiment of the present application, the on-resistance of the NMOS device can still be reduced by separately configuring the annealing temperatures of the annealing process of the zeroth metal layer.

FIG. 6B is a chart comparing the threshold voltages containing metal gate NMOS transistors on four wafers which are annealed at different temperatures for the zeroth metal layer, according to the embodiment of the present application. The threshold voltages of each data group are measured on each wafer, for example the threshold voltages corresponding to data groups 303a and 303b are threshold voltages of the device on the wafers that undergo the first annealing process 601 and the second annealing process 602.

In FIG. 6B, the devices on four wafers annealed at two temperatures show their resultant threshold voltages on the Y-axis as data groups 303a and 303b annealed at 650° C.+600° C. in both the first annealing process 601 and the second annealing process 602. The threshold voltages in data groups 304a and 304b on the two wafer that undergo the annealing process of the zeroth metal layer at 650° C. The threshold voltages of the data groups 303a and 303b are substantially similar to the threshold voltages of the data groups 304a and 304b, thus the method according to this embodiment of the present application can result in the threshold voltage of the NMOS reach the target value.

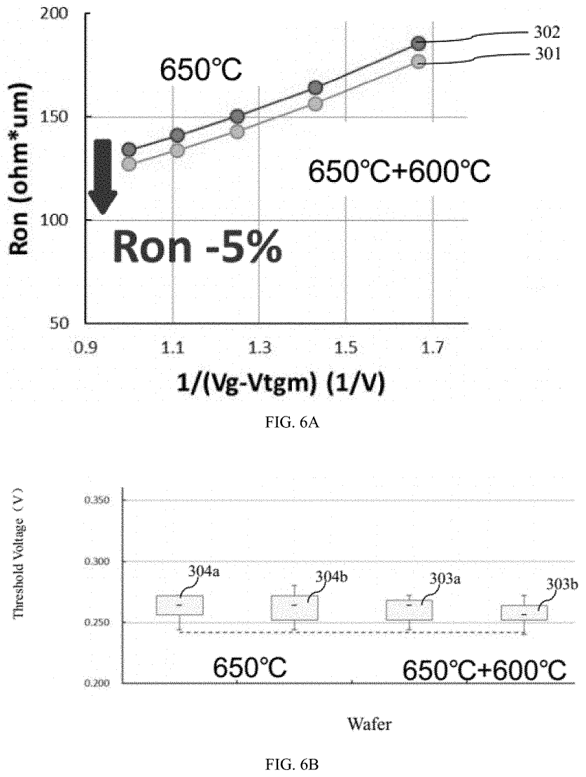

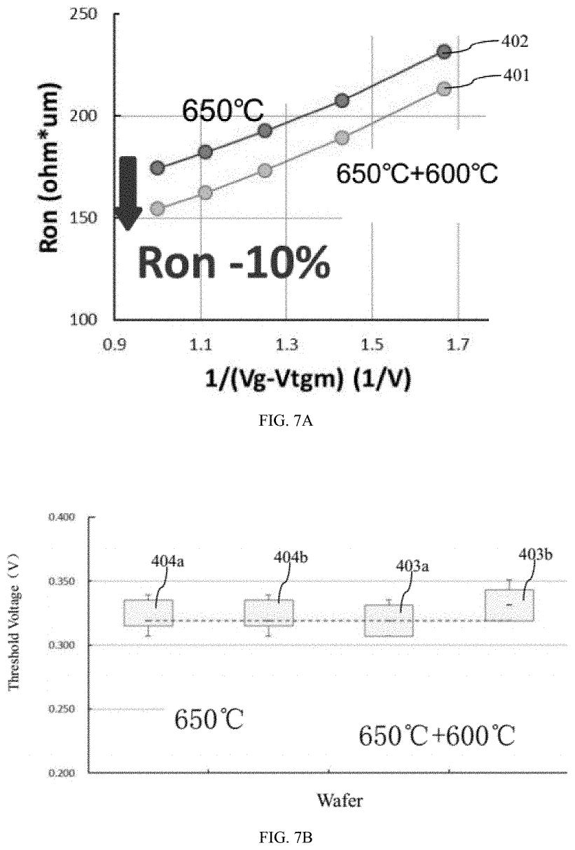

FIG. 7A is a chart of on-resistance (Ron) versus the inverse of gate voltage minus threshold gate voltage (Vg−Vtgm)⁻¹ at two different annealing temperatures at zeroth-metal-layer of an PMOS device, by the method for manufacturing the metal gate MOS transistor according to the embodiment of the present application. Curve 401 represents the on-resistance when the first annealing process 601 and the second annealing process 602 according to this embodiment of the present application are performed. The first anneal temperature and the second anneal temperature are 650° C. and 600° C., respectively. In FIG. 7A, 650° C.+600° C. is applied to indicate that the first annealing process 601 and the second annealing process 602 of this embodiment of the present application are performed. Curve 402 represents an on-resistance obtained after the annealing process of the zeroth metal layer at 650° C. is performed. The value of the curve 401 is lower by about 10%. Therefore, in this embodiment of the present application, the on-resistance of the PMOS device can still be reduced by separately configuring the annealing temperatures of the annealing process on the zeroth metal layer.

FIG. 7B is a chart comparing the threshold voltages containing metal gate PMOS transistors on two wafers which are annealed at different temperatures for the zeroth metal layer, according to the embodiment of the present application. In FIG. 7B the devices on four wafers annealed at two temperatures show their resultant threshold voltages on the Y-axis as data groups 303a and 303b annealed at 650° C.+600° C. in both the first annealing process 601 and the second annealing process 602. The threshold voltages of data groups are measured for each wafer, wherein the threshold voltages for data groups 403a and 403b from the respective wafers that undergo the first annealing process 601 and the second annealing process 602 of this embodiment of the present application. In FIG. 7B, 650° C.+600° C. is applied to indicate that the first annealing process 601 and the second annealing process 602. The threshold voltages corresponding to data groups 404a and 404b are threshold voltages of the device from the wafers that undergo the annealing process of the zeroth metal layer at 650° C. It can be seen that the threshold voltages of the data groups 403a and 403b are substantially similar to the threshold voltages of the data groups 404a and 404b, thus the method according to this embodiment of the present application enables the PMOS devices reach the target value of the threshold voltage.

The present application is described in detail above via specific embodiments, which, however, are not intended to limit the present application. Without departing from the principles of the present application, those skilled in the art can also make many modifications and improvements, which should also be regarded as the protection scope of the present application.

What is claimed is:

1. A method for manufacturing a metal gate MOS transistor, comprising following steps:
step 1, forming metal gates on a semiconductor substrate, and forming a zeroth interlayer film in a spacing between adjacent two of the metal gates;
step 2, forming a first dielectric layer on the metal gates and the zeroth interlayer film;
step 3, selecting a region for forming a zeroth metal layer, and etching the first dielectric layer and the zeroth interlayer film in the region to form an opening for the zeroth metal layer;
step 4, forming a first Ti layer and a second TiN layer on an inner side surface of the opening of the zeroth metal layer; and
step 5, forming the zeroth metal layer by filling the opening with a metal material; to wherein the method further comprises, after the step 1 and before the step 4:
performing a first annealing at a first temperature for adjusting a threshold voltage of the metal gate MOS transistor to a target value by setting the first temperature; and
wherein the method further comprises, after step 4 and before step 5:
performing a second annealing at a second temperature for adjusting an on-resistance of the metal gate MOS transistor and reducing the on-resistance by reducing the second temperature;
wherein the second temperature is lower than the first temperature.

2. The method according to claim 1, wherein in step 1, the metal gates are formed by means of a gate-last process.

3. The method according to claim 2, wherein the gate-last process comprises:
removing dummy polysilicon gates; and
forming the metal gates where the dummy polysilicon gate are removed.

4. The method according to claim 2, wherein each one of the metal gates comprise a metal work function layer and a metal conductive material layer stacked in sequence.

5. The method according to claim 4, wherein a material of the metal conductive material layer comprises tungsten.

6. The method according to claim 5, wherein a material of the zeroth metal layer comprises tungsten.

7. The method according to claim 6, wherein the first temperature is in a range of 650° C.-700° C.

8. The method according to claim 7, wherein the second temperature is in a range of 550° C.-600° C.

9. The method according to claim 5, after forming the metal gates in step 1, further comprising a step of etching back the metal conductive material layer.

10. The method according to claim 9, before forming the first dielectric layer in step 2, further comprising:
a step of forming a second dielectric layer to fill an etching-back region of the metal conductive material layer;
wherein a material of the first dielectric layer is a same as a material of the zeroth interlayer film, and a material of the second dielectric layer comprises silicon nitride; and
wherein the second dielectric layer is formed by means of a deposition process, and wherein the method further comprises performing planarization by means of a chemical mechanical polishing process after the deposition process.

11. The method according to claim 4, wherein in step 1, a gate dielectric layer is disposed between the metal gates and the semiconductor substrate.

12. The method according to claim 11, wherein the gate dielectric layer comprises a high dielectric constant layer.

13. The method according to claim 12, wherein the metal gate MOS transistor is a fin transistor, wherein fins are formed on the semiconductor substrate by patterning the semiconductor substrate; and
wherein the metal gates are disposed on a top surface and side surfaces of one of the fins.

14. The method according to claim 13, wherein step 1 further comprises, forming a source region and a drain region in the fins on two sides of each one of the metal gates.

15. The method according to claim 4, wherein the metal gate MOS transistor comprises an NMOS and a PMOS.
